(19) United States
(12) Patent Application Publication
(10) Pub. No.: US 2006/0083343 A1
(43) Pub. Date: Apr. 20, 2006

(54) Clock generation using phase interpolators

(75) Inventors: Benoit Roederer, San Jose, CA (US); Masahiro Konishi, Cupertino, CA (US)

Correspondence Address: OLIFF & BERRIDGE, PLC, P.O. BOX 19928, ALEXANDRIA, VA, 22320, US

(73) Assignee: KAWASAKI MICROELECTRONICS, INC., Chiba-shi (JP)

(21) Appl. No.: 10/967,168

(22) Filed: Oct. 19, 2004

(51) Int. Cl. H03D 3/24

(52) U.S. Cl. 375/375

(57) ABSTRACT

A serial data link, which derives an incoming data clock linked to the data rate of the incoming data, also generates an outgoing data clock that is used to re-transmit the data from the serial link into the communications channel. The incoming and outgoing data clocks are derived from a single local oscillator, using dual phase interpolating circuits to adjust the phase lead/lag to match the incoming data rate.

### BACKGROUND OF THE INVENTION

1 Field of Invention

This invention relates to systems and methods for handling data in a communications network.

2. Description of Related Art

Communications networks may transmit data from a source to a destination, through one or more serial data links. The serial data links receive the data from the data source, and re-transmit the data to a data destination. Often, the data is transmitted without an explicit clock signal, such as in a clockless communications network. In a clockless communications network, in order to maintain data synchronization between the data source and the data destination, the serial data link must derive a clock signal from the transmitted data itself. The serial data link then re-transmits the data to the data destination according to the derived clock signal. In order for the serial data link to derive a correct clock signal and maintain data synchronization, the clock rate of the data source is not allowed to vary outside of a predefined range.

One example of a clockless communications network is a fiber optic network. Because of their very high data rates, fiber optic networks have proliferated and become a prevailing technology for short-haul and long-haul communications networks. In fiber optic networks, data is transmitted along a high speed data transmission backbone, before being distributed along the branches of the networks to their final destination. Techniques such as dense wavelength divisional multiplexing (DWDM) have increased the data rate of the data backbone by multiplexing the data on different optical transmission frequencies, which are combined and sent down the data backbone. Optical signal splitters situated at the junctions of the branches of the network with the trunk divide the signals according to their routing addresses, or, in the case of dense wavelength divisional multiplexing, according to the frequencies, and deliver the signals to the appropriate destinations.

The splitters may be composed only of passive optical components, and thus may be a unit of a passive optical network (PON). The passive optical network is a network of point to multi-point fiber links that connect a central office interface unit (COIU) to the optical network units (ONUs). In order to minimize repair and maintenance costs, passive optical networks include only passive optical devices, such as beamsplitters, rather than active optical devices, such as optical amplifiers. The optical network units terminate the passive optical network at or near a customer's premises, where they convert the optical signal into electronic signals using electro-optic devices, and deliver the electronic signals to a twisted pair or parallel cable to the user's equipment. The optical network units may reside at the curb (fiber-to-the-curb, FTTC), in a building (fiber-to-the-building, FTTB), or at home (fiber-to-the-home, FTTH). The optical network units can be configured to provide voice, data and optional video services to remote customers. Supported user network interfaces (UNIs) include plain old telephone service (POTS), integrated services digital network (ISDN), 10/100 Base-T Ethernet, and radio-frequency (RF) coaxial cable for cable television (CATV).

The electro-optic devices may perform two-way conversion between the optical signals and the electronic signals. The optical network units receive signals generated by the user's equipment for transmission back into the fiber optic network. Therefore, the optical network units include synchronized data links which provide end-to-end, bi-directional synchronized communications. Using the synchronized data link, the data may be re-transmitted into the fiber optic network at the same data rate at which it was received, but without a data clock. Therefore, the optical network units need to generate an outgoing data clock which corresponds to the data rate of the incoming data. Since no data clock is transmitted with the data (i.e. the data clock is implicit), a data clock must be derived from the incoming data, and then used to re-transmit the data to its downstream destination.

### SUMMARY OF THE INVENTION

Because of the extensive use of communications networks, such as fiber optic communications networks for homes and offices, there is a continued need to reduce the cost and/or complexity of the devices used to implement the communications networks. Reducing the complexity of the devices also helps to reduce maintenance costs and improve the reliability of the service.

A serial data link derives an incoming data clock which is linked to the data rate of the incoming data, and also generates an outgoing data clock used to re-transmit the data from the serial link into the communications channel. The incoming and outgoing data clocks may be derived from a single local oscillator using dual phase interpolating circuits to adjust the phase lead/lag to match the incoming data rate. Only a single oscillator may be used, thus reducing the costs of implementation and/or maintenance.

A clock, data recovery and de-serializer module may compare a rising and/or falling edge of a clock generated by a local oscillator with a rising and/or falling edge of a data transition. The comparison yields a value for the phase error between the data edge and the clock edge. This phase error may be fed into a phase interpolator, which generates a signal at the local oscillator frequency in which the phase is advanced or retarded according to the phase error. By updating the phase error frequently, the clock generated by the phase interpolator based on the local oscillator will have, on average, exactly the right frequency for detecting the data. The phase error generated by the clock, data recovery and de-serializer module may then be filtered with a low pass filter. The filtered value may be fed into a second phase interpolator. This second phase interpolator generates a signal at the frequency of the local oscillator with a phase that is advanced or retarded according to the filtered value of the phase error. The signal output from the second phase interpolator may serve as the outgoing data clock for a serializer, which serializes the parallel data and transmits the date synchronously according to the outgoing data clock from the second phase interpolator. Since the outgoing data clock from the second phase interpolator is derived from the same data clock and phase error as was input to the first phase interpolator, the data is transmitted out synchronously at the same rate at which the data was transmitted in.

Various details of this invention are described in, or are apparent from, the following detailed description.

### BRIEF DESCRIPTION OF THE DRAWINGS

Various details of this invention will be described with reference to the following figures, wherein:

FIG. 1 is a block diagram of an exemplary environment in which a serial data link can operate;

FIG. 2 shows an exemplary optical network unit in greater detail;

FIG. 3 is a block diagram illustrating an exemplary serial data link;

FIG. 4 is a diagram illustrating an exemplary method of detecting data transitions in incoming data using an oscillator clock;

FIG. 5 is a diagram illustrating an exemplary measurement of a phase lead error;

FIG. 6 is a diagram illustrating an exemplary measurement of a phase lag error;

FIG. 7 is a diagram illustrating the operation of an exemplary phase interpolator;

FIG. 8 is a diagram illustrating features of an exemplary phase interpolated clock signal;

FIG. 9 is a diagram illustrating the behavior of an exemplary interpolated clock frequency;

FIG. 10 is a diagram illustrating the behavior of the interpolated clock frequency over a plurality of phase refresh periods according to an exemplary embodiment of the invention;

FIG. 11 is a diagram illustrating the operation of a finite impulse response filter according to an exemplary embodiment of the invention;

FIG. 12 is a diagram illustrating the generation of the output data clock for the exemplary serial data link of FIG. 3;

FIG. 13 is a block diagram illustrating a known serial data link;

FIG. 14 is a diagram illustrating the operation of the phase-locked loop of the known serial data link of FIG. 13;

FIG. 15 comparatively illustrates the behavior of the outgoing data clock signal generated by an exemplary dual phase interpolator circuit compared to that generated by the phase-locked loop of the known serial data link of FIG. 13; and

FIG. 16 is a flowchart illustrating an exemplary method for generating an outgoing data clock signal using the serial data link of FIG. 3.

### DETAILED DESCRIPTION OF EXEMPLARY EMBODIMENTS

Systems and methods are described for detecting a series of incoming data pulses, recovering an incoming data clock from the data pulses, and re-transmitting the data pulses based on an outgoing data clock. Both the incoming data clock and the outgoing data clock may be derived from a single local oscillator and dual phase interpolators. Such systems and methods may be used for any clockless serial data transmissions. For clarity of illustration, a fiber optic communications network will be discussed as one example. However, it should be understood that the invention is not so limited, and may be applicable to other systems in which data is exchanged between devices.

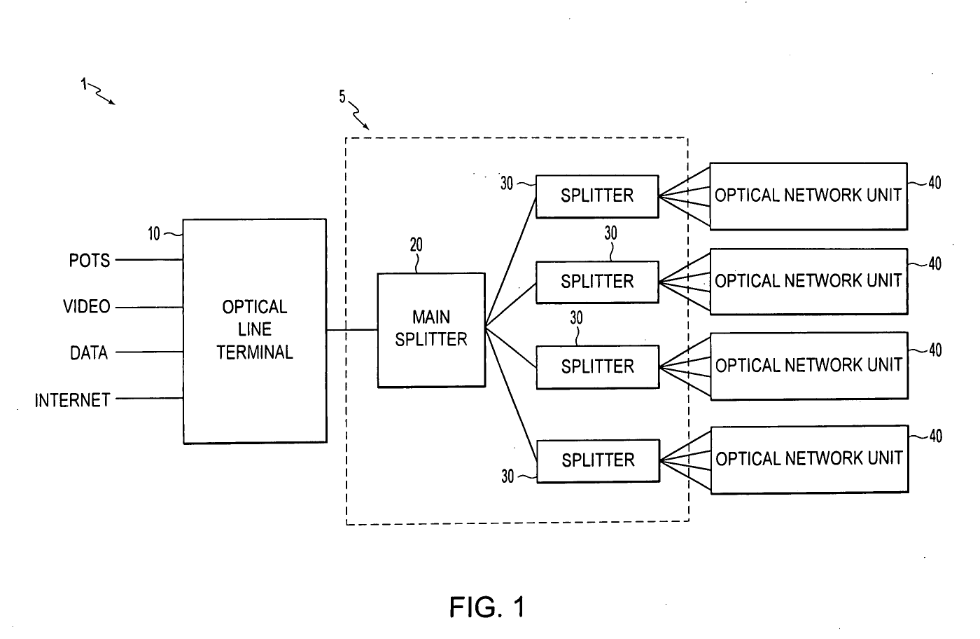

FIG. 1 is a block diagram of an exemplary fiber optic network 1 in which the systems and methods may be implemented. In network 1, an optical line terminal 10 generates a light signal from any of a plurality of data sources, including plain old telephone service (POTS), video, data and/or internet traffic. Optical line terminal 10 then sends the optical signal down a fiber optic cable to a main splitter 20, which splits the signal according to the destination address of the data, for example. The optical signal is then transmitted to secondary splitters 30, which further route the data to an appropriate destination. Typically, secondary splitters 30 split the signal in a four-to-one ratio, so that each outgoing signal carries a quarter of the incoming power. The splitters 20 and 30 form a passive optical network 5 because, for this example, only passive optical components are used in this portion of the network 1. The secondary splitters 30 then feed the optical signal to a plurality of optical network units (ONUs) 40. Optical network units 40 may include electro-optic devices that may terminate the optical portion of the network, and typically deliver the data to the user's application as electronic data pulses.

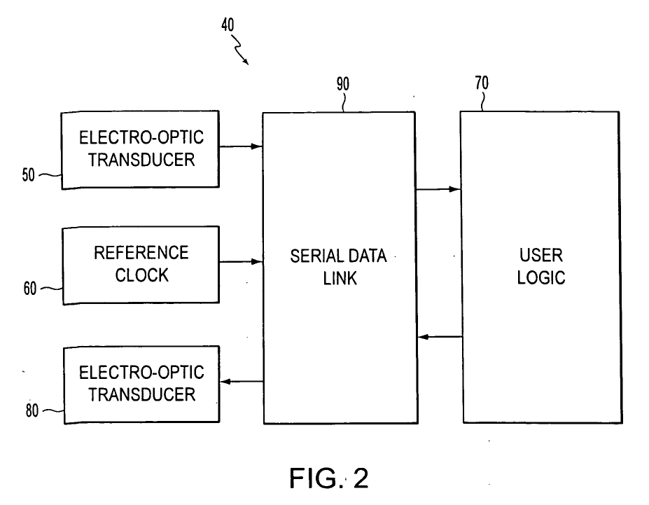

FIG. 2 shows an exemplary optical network unit 40. Optical network unit 40 includes electro-optic hardware, such as an electro-optic transducer 50, for converting the optical signals into electrical signals for use by the user's equipment. The electro-optic transducer 50 may be, for example, a photodiode. Optical network unit 40 may also include an electro-optic transducer 80 for re-transmitting the data back into the fiber optic network. Electro-optic transducer 80 may be, for example, a laser diode, wherein data is encoded as amplitude or frequency variations on a carrier frequency.

Optical network unit 40 may also include a serial data link 90 that detects the incoming electrical pulses and decodes the data as a series of ones and zeros. The serial data link 90 may re-format the data from a serial format to 8-bit or 16-bit parallel format, for example, or into a digital subscriber line (DSL) serial format, depending on the architecture of a user's logic 70. Serial data link 90 then transmits the re-formatted data along with the data clock recovered from the data to the user's logic 70. User logic 70 will then buffer the received data in memory, for use by the user's application.

Optical network unit 40 may also include a reference clock 60 for serial data link 90. Reference clock 60 provides a reference signal for the generation of a data clock, with which the serial data link 90 will detect the incoming data from electro-optic transducer 50 and transmit the data to user logic 70. The reference signal is typically at a frequency ten times lower than the data clock, so that in this embodiment, the reference signal may have a frequency of 125 MHz to drive a data clock of 1.25 GHz. The data rate of the fiber optic network is typically 1.25 GHz, transmitted on coherent infrared diode laser light of a wavelength of 1550 nm, for example.

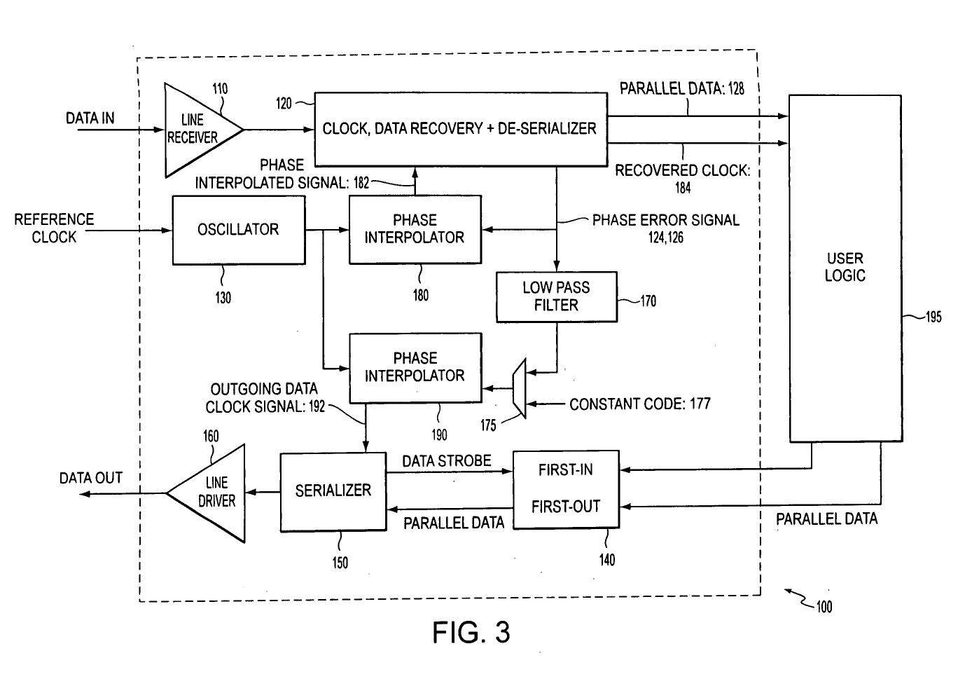

FIG. 3 illustrates an exemplary serial data link 100. Serial data link 100 includes a line receiver 110, a clock, data recovery and deserializer module 120, an oscillator 130, a phase interpolator 180, a low pass filter 170, a first-in-first-out buffer 140, a second phase interpolator 190, a serializer 150, and a line driver 160. For clarity, the overall data flow through the serial data link 100 will be described first, followed by a detailed description of the data detection and clock generation circuitry of serial data link 100.

Line receiver 110 of serial data link 100 may be a low impedance amplifier that amplifies the signals from the electro-optic transducer 50. Line receiver 110 then sends amplified signal 112 to a clock, data recovery and de-serializer module 120. The clock, data recovery and de-serializer module 120 detects the data using an oscillator clock signal 132 generated by an oscillator 130 based on the reference clock signal. As described above, the oscillator clock signal 132 generated by oscillator 130 may operate at 1.25 GHz.

Clock, data recovery and de-serializer module 120 then sends the detected data in the appropriate format, parallel or serial, to user logic 195. The user logic 195 buffers the input data and re-transmits outgoing data to a first-in-first-out data buffer 140. The first-in-first-out buffer 140 then transmits the data to a serializer 150, which reconstructs a serial data stream from the parallel data, and transmits it to line driver 160. Line driver 160 may be a high gain amplifier for amplifying the signal levels before sending them, for example, to electro-optic transducer 80 of FIG. 2, for re-transmission, for example, into the passive optical network 5 of FIG. 1.

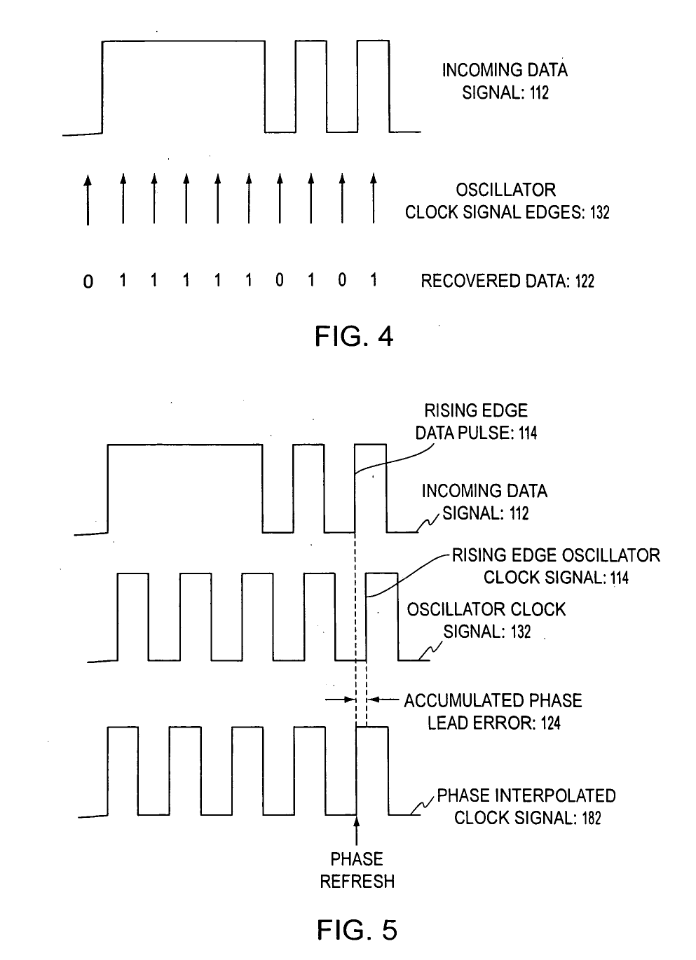

Clock, data recovery and de-serializer module 120 analyzes incoming data signal 112 generated by line receiver 110 by sampling incoming data signal 112 at intervals determined by a data clock, which may be the oscillator clock signal 132. FIG. 4 illustrates an exemplary method of data detection used by the clock, data recovery and de-serializer module 120. In this example, the edges of the oscillator clock signal 132 occur at about the same frequency as the data rate, although often, clock rates higher than the data rate, for example, sixteen times the data rate, may be used. The incoming data signal 112 is sampled on the rising and/or falling edge of each clock pulse. If incoming data signal 112 is higher than a predefined threshold, a logical “one” is detected; if incoming data signal 112 is lower than the predefined threshold, a logical “zero” is detected. The recovered data 122 is then output as a string of logical ones and zeroes. The logical ones and zeroes are then reformatted as 8-bit or 16-bit parallel data 128, and output to the user logic. Therefore, by sampling the incoming data signal 112 at intervals defined by the occurrence of the oscillator clock signal edges 132, the recovered data 122 is generated.

In general, oscillator clock signal 132 is asynchronous, that is, slightly detuned from the frequency of the incoming data 112. In addition, the frequency of the incoming data signal 112 may vary over a narrow range. The difference between the frequency of the oscillator clock signal 132 and the incoming data signal 112 is detected as a phase error by clock, data recovery and de-serializer module 120. Clock, data recovery and de-serializer module 120 compares the timing of a rising (or falling) edge of incoming data signal 112, with a rising or falling edge of oscillator clock signal 132, and digitizes this phase error. For example, as illustrated in FIG. 5, incoming data signal 112 may have a frequency that is slightly shorter than oscillator clock signal 132. Therefore, the rising edge 114 of incoming data signal 112 may lead the rising edge 134 of oscillator clock signal 132, resulting in a detected phase lead error 124. Although for clarity of depiction, the phase lead error 124 is shown as being generated from a single comparison of the rising (or falling) edges of a single data pulse, in other implementations, clock, data recovery and de-serializer unit 120 may accumulate phase lead error 124 by measuring the phase difference over a plurality of pulses, for example, 16 pulses, and update the digitized value of phase lead error 124 every 16^{th} pulse.

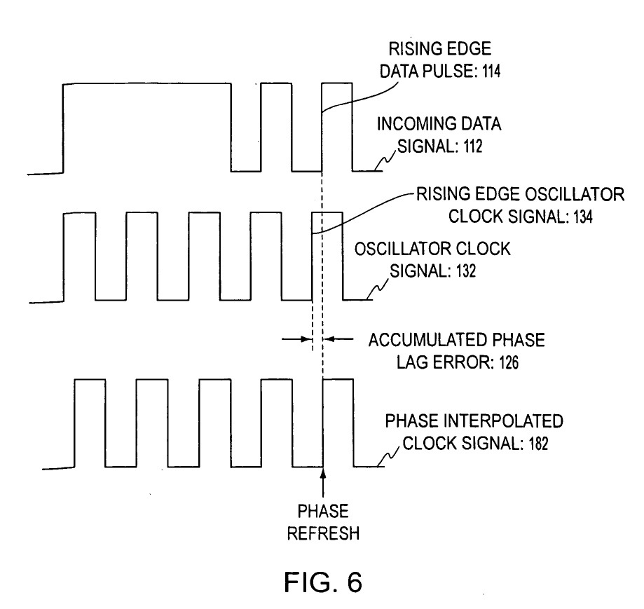

Alternatively, as illustrated in FIG. 6, incoming data signal 112 may have a frequency which is slightly longer than the frequency of oscillator clock signal 132. In this case, clock, data recovery and de-serializer module 120 will measure a phase lag error 126 between incoming data signal 112 and oscillator clock signal 132. Again, for clarity of depiction, phase lag error 126 is shown as being generated from a single comparison of the rising (or falling) edges of a single data pulse. However, in other implementations, clock, data recovery and de-serializer module 120 may accumulate phase lag error 126 by measuring the phase lag over a plurality of pulses, for example, 16 pulses, and update the value of phase lag error 126 every 16^{th} pulse.

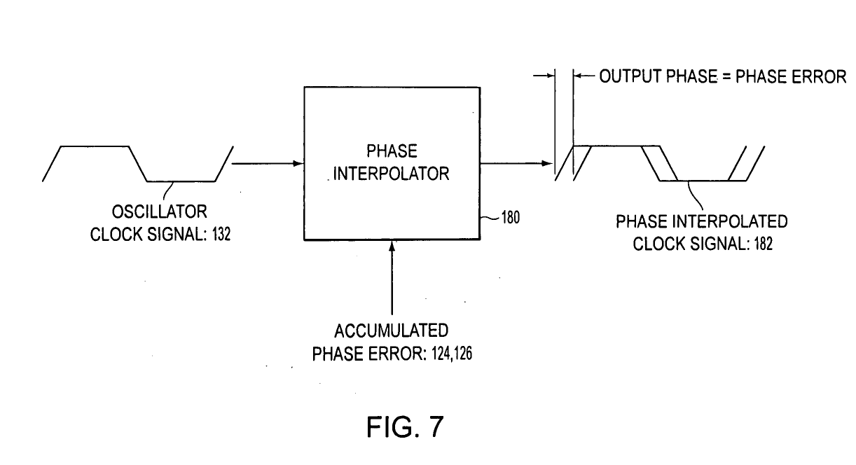

A recovered clock having an average frequency that is adjusted to match the incoming data frequency exactly is generated using a phase interpolator 180. The function of phase interpolator 180 is shown in greater detail in FIG. 7. The inputs to phase interpolator 180 are the oscillator clock signal 132 and the digitized value of the phase lead error 124 or phase lag error 126 calculated by clock, data and recovery de-serializer module 120. Phase interpolator 180 generates an interpolated output signal 182 of the same frequency as oscillator clock signal 132, but with a phase that is adjusted relative to the phase of oscillator clock signal 132, according to the digitized value of phase error 124 or 126 input to phase interpolator 180 from clock, data recovery and de-serializer module 120.

Therefore, although the instantaneous frequency of interpolated output signal 182 from phase interpolator 180 will continue to have a slight mismatch from the incoming data frequency, the average frequency of interpolated output signal 182 of phase interpolator 180 will exactly match the incoming data frequency.

Clock, data recovery and de-serializer module 120 may evaluate the magnitude of phase error 124, 126, and only send phase error 124, 126 to phase interpolator 180 if phase error 124, 126 exceeds a predefined value. Accordingly, phase interpolator 180 may update the phase less frequently than clock, data recovery and de-serializer module 120 can produce phase errors 124, 126.

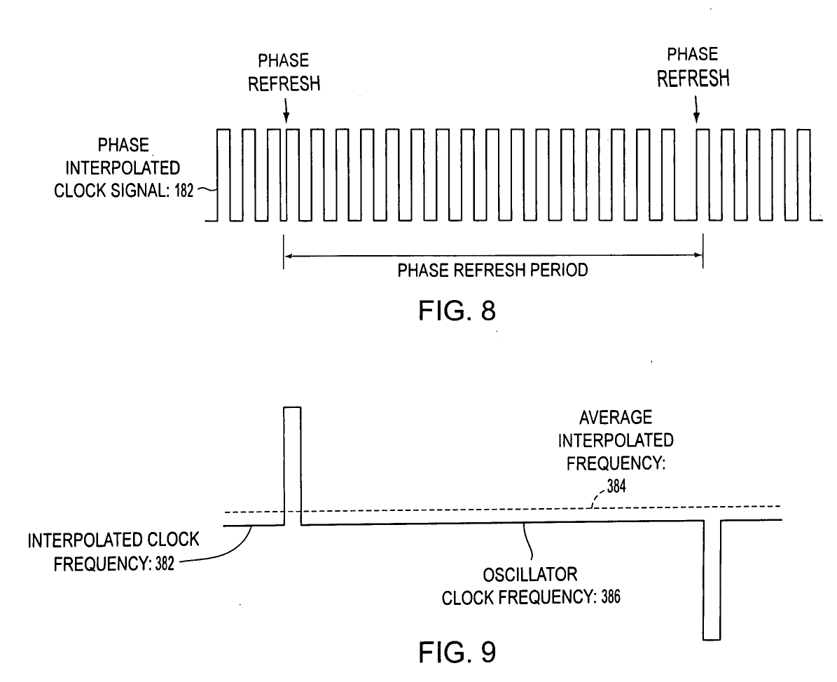

The functioning of phase interpolator 180 is shown qualitatively in FIGS. 8 and 9. Although for ease of depiction and clarity of discussion, the updating of the phase of the phase interpolated clock is shown to occur essentially instantaneously, it should be understood that in actuality, phase interpolator 180 may require some number of clock cycles to implement the phase correction on phase interpolated clock signal 182. Phase interpolator 180 may implement the phase change over a period of sixteen clock cycles, for example. During the period in which phase interpolator 180 is implementing the corrected phase, the effective frequency of phase interpolated output signal 182 is changed, in order to accommodate the phase error. For example, as shown in FIG. 8, at the first “phase refresh” incidence in phase interpolated clock signal 182, a phase lead error was input to the phase interpolator, such as the phase lead error 124 shown in FIG. 5.

Phase interpolated output signal 182 can be characterized by a phase interpolated output frequency 382. Phase interpolator 180 increases the phase interpolated output frequency 382 over a short period of time, shown as the “phase refresh” period until the phase lead is accommodated. When the phase lead is accommodated, the phase lead error from clock data recovery and de-serializer module 120 drops to zero, and the phase interpolated signal 382 reverts to the frequency of oscillator clock 132. However, over the short period during the accommodation of the phase lead, the phase interpolated clock signal frequency 382 increases, as shown in FIG. 9. Therefore, although this phase refresh is depicted to occur over only one or two clock cycles, it should be understood that in actuality, the phase error may be corrected over a longer period of time, for example, sixteen clock cycles.

Also as shown in FIG. 8, phase interpolated clock signal 182 may also accommodate a phase lag, such as phase lag 126 shown in FIG. 6. To accommodate a phase lag, the output frequency 382 of the phase interpolated clock signal 182 is reduced slightly, until the phase difference between phase interpolated output signal 182 and oscillator clock 132 is equal to the digitized value of phase error 126 input to phase interpolator 180.

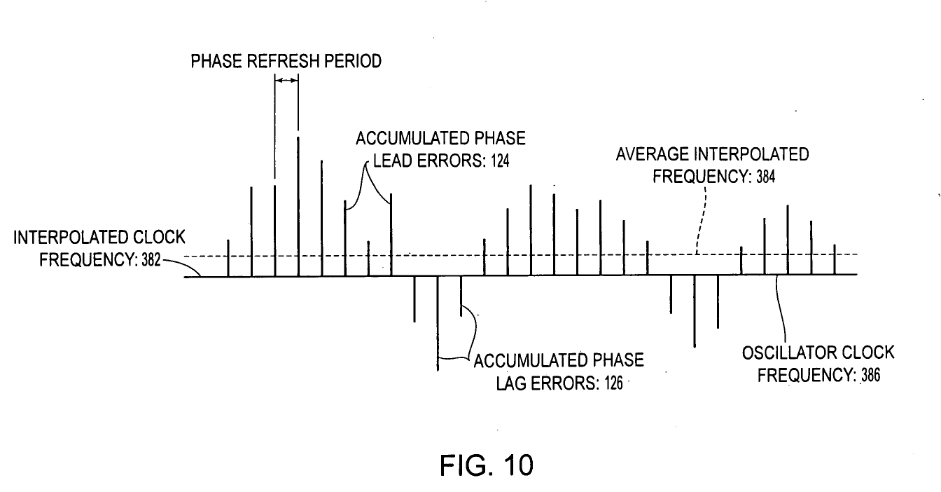

By constantly updating the accumulated phase error input to phase interpolator 180, phase interpolator 180 outputs a phase interpolated output signal 182 whose average frequency 384 exactly matches the frequency of incoming data signal 112. This is shown in FIG. 10, which illustrates the behavior of the phase interpolated clock frequency 382 over a plurality of phase refresh periods. When viewed over the longer time frame shown in FIG. 10, the phase interpolated clock frequency 382 is usually at the oscillator clock frequency 386; however, the average frequency 384 is somewhat higher, because incoming data signal 112 had a slightly higher frequency, causing phase lead errors to occur frequently. The frequent phase lead errors cause the phase interpolator circuit to frequently increase the output frequency so that the phase of the phase interpolated output signal 182 catches up to the phase of incoming data signal 112. Accordingly, the average frequency 384 of interpolated clock signal 182, as shown by the dashed line in FIG. 10, is slightly higher than the oscillator clock frequency 386.

The resolution (i.e. length) of the digital code may be determined by the architecture of phase interpolator 180. This resolution of the phase error, and the frequency with which the phase error is updated, determine the maximum frequency differential between incoming data signal 112 and oscillator clock frequency 384 that can be accommodated by phase interpolator 180. For example, if clock, data recovery and de-serializer module 120 refreshes the phase error every 16 clock periods, and the maximum resolution of the digital code is one part in 64 (i.e., the phase error is a six-bit long word), then the maximum allowed frequency difference between the incoming data signal 112 and the oscillator clock signal 132 is 1/(64*16)=0.0976%, or 976 parts-per-million. Therefore, using an oscillator 130 operating at 1.25 Ghz, a maximum rate of 1.25122 Gbps and a minimum data rate of 1.24878 Gbps can be accommodated.

The various components in this example may use digital signals to accomplish their tasks. For example, phase interpolator 180 accepts a digital input value for the phase error. However, other implementations may use analog components and signal levels to accomplish the same function. For example, clock, data recovery and de-serializer module 120 may generate an analog signal level for the phase error, which is accepted by an analog phase interpolator, which generates an output signal with a phase delay proportional to the analog signal level.

Returning to FIG. 3, clock, data recovery and de-serializer module 120 outputs phase interpolated clock signal 182 as the recovered clock signal 184 to the user logic 195. In the case of clock, data recovery and de-serializer module 120 outputting parallel data, recovered clock 184 may be phase interpolated clock signal 182 divided by 8 or 16, depending on whether the output data is 8-bit parallel or 16-bit parallel.

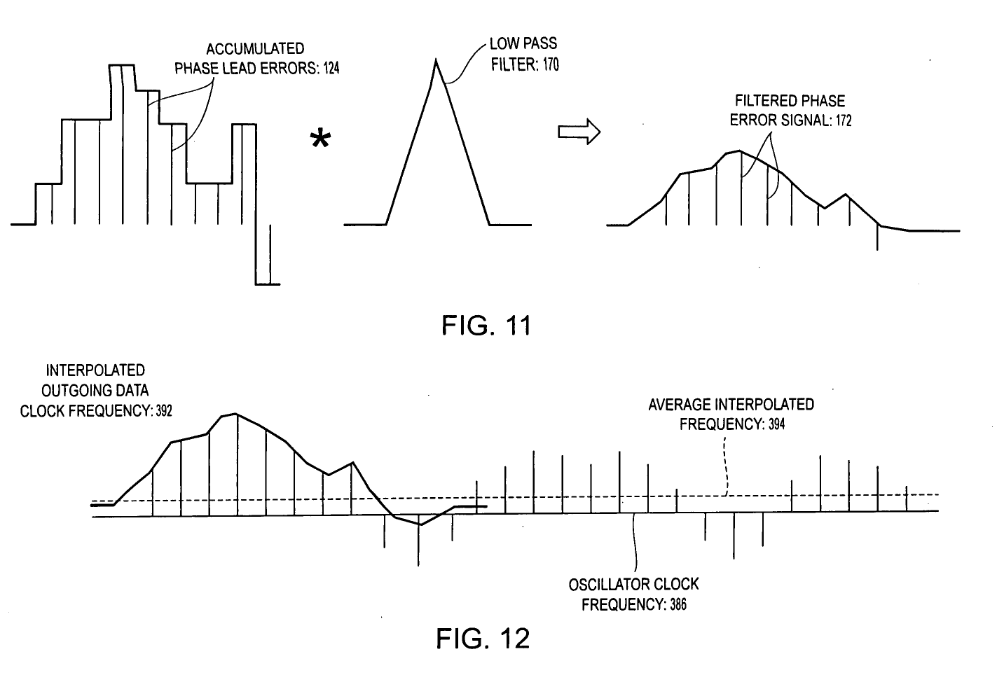

Serial data link 100 then generates an outgoing data clock signal 192 using the same accumulated phase error 124, 126 generated by clock, data recovery and de-serializer module 120 using a second phase interpolator 190, as shown in FIG. 3. To generate outgoing data clock signal 192, accumulated phase error signals 124 and 126 are first put sequentially though a low-pass filter 170, for example, a symmetric finite impulse response filter, such as that shown diagrammatically in FIG. 11. The parameters of the low-pass filter are chosen to filter out high frequency jitter, while transmitting the relatively low-frequency frequency variations of the phase errors. As a result, much of the high frequency jitter of the phase errors is removed to generate a filtered phase error signal 172. The filtered phase error signal 172 has the same basic envelop shape as accumulated phase lead errors 124 and accumulated phase lag errors 126, but smoothed by the operation of low pass filter 170, as shown in FIG. 11.

Filtered phase error signal 172 is then input to a second phase interpolator 190, along with oscillator clock signal 132 from oscillator 130. Second phase interpolator 190 may operate in a manner similar to that described above for first phase interpolator 180. Second phase interpolator 190 generates a phase interpolated outgoing data clock signal 192 having a time-dependent frequency 392, as shown in FIG. 12. The nominal frequency of the outgoing data clock signal is the same as oscillator clock signal 132; however, because of frequent phase updates by filtered phase error signal 172, the average frequency 394 of the outgoing data clock signal is exactly synchronous with incoming data signal 112. While on this time scale, the average frequency 394 of outgoing data clock signal 192 and the frequency of incoming data signal 112 appear constant, the frequency of the incoming data, and therefore the frequency of the outgoing data clock signal, can be seen to vary over a longer time span. However, because the phase interpolators are both linked to the incoming data signal by the phase error, both phase interpolated clock signal 182 and outgoing data clock signal 192 remain synchronous with the incoming data signal.

An exemplary low pass filter suitable for use in the example shown in FIG. 3 is a finite impulse response filter 170, such as that shown in FIG. 111. The phase error signal may first be decimated by a factor of four, for example, to generate a subset of error samples wherein only every fourth error value is retained. The error samples are then delayed by a given interval of time, and multiplied by the coefficients of the finite impulse response filter. Each product is then added to a running sum of the products of each coefficient times the sample value. The output of the filter is then the total sum of the products of each coefficient and error sample for the sample at the given delay. Because the application of a finite element impulse response filter results in a total delay which is equal to the number of coefficients times the delay between each sample of the error signal, the filtered phase error signal is delayed in time relative to the unfiltered phase errors.

Having generated outgoing data clock signal 192, serial data link 100 is ready to re-transmit data to the passive optical network 5. Returning to FIG. 3, the serializer 150 of the serial data link 100 strobes the first-in-first-out buffer 140 to send a set of parallel data received from user logic 195, which serializer 150 then re-formats into serial form, before transmitting the data to line driver 160. The data is transmitted to line driver 160 at the clock rate of the outgoing data clock, generated by the second phase interpolator 190 which, as described previously, is derived from the same oscillator as the recovered data clock. Therefore, the outgoing data clock is nearly a perfect copy of the clock used by clock, data recovery and de-serializer module 120, and link 100 is unconditionally synchronous. Line driver 160 may be an amplifier that amplifies the signals to an appropriate level for encoding into optical pulses by electro-optic transducer 80 for re-transmission into the fiber optic network.

An asynchronous mode can also be conveniently implemented using the circuit of FIG. 3. For the asynchronous mode, a multiplexer 175 switches the input to the second phase interpolator 190 to a constant code 177. This constant code 177 is a constant digital value of a phase error, which is not updated by clock, data recovery and de-serializer module 120. Because the phase error is no longer updated, the second phase interpolator 190 will output a single frequency waveform at the frequency of the oscillator 130, but which is updated periodically according to the phase error given by the constant code 177. Therefore, the output of the second phase interpolator 190 is a single frequency which jumps briefly to a higher frequency at each phase refresh interval, in order to accommodate the phase error. Thus, the outgoing data clock signal 192 produced by the second phase interpolator 190 has the same average frequency as incoming data signal 112, although it has a nominal frequency which is that of oscillator 130.

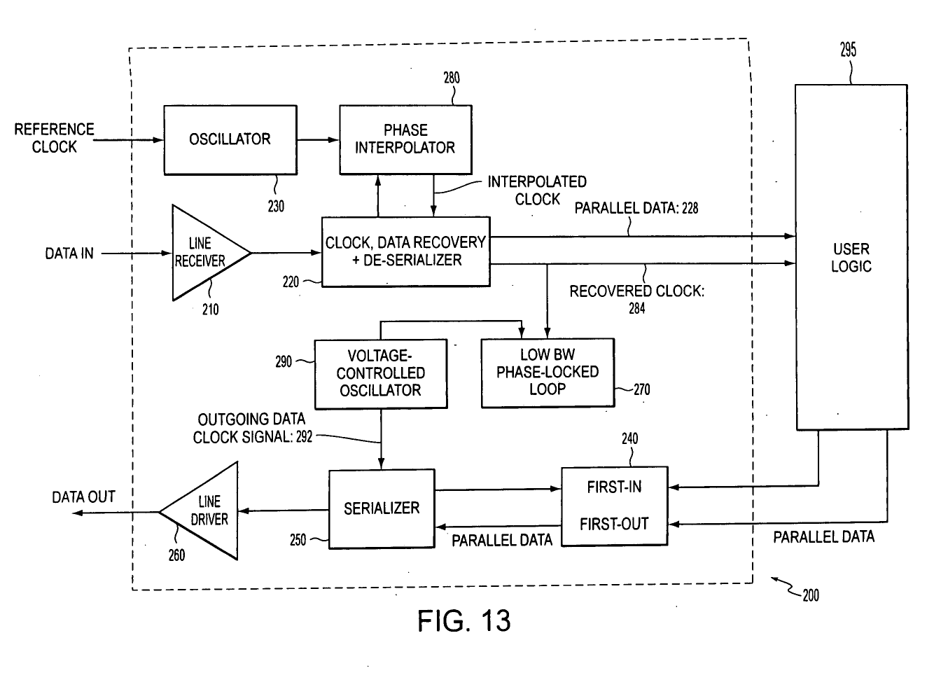

The circuit shown in FIG. 3 is distinctly different from known serial data links such as serial data link 200, depicted in FIG. 13. (See, for example, WO 98/45973). In FIG. 13, the outgoing data clock signal 292 is generated by a phase locked loop which locks a frequency of a second (voltage controlled) oscillator 290 to the frequency of the recovered clock 284. Clock timing jitter is reduced by making the phase locked loop operate in a low bandwidth regime, wherein the response of the voltage controlled oscillator 290 is slow compared to the changing frequency of the recovered clock. The recovered clock 284, generated by the phase interpolator 280, has a varying phase which is measured by the phase detector of the phase locked loop. Any difference between the phase of the recovered clock 284 and the phase of the output of the voltage controlled oscillator 290 generates a voltage error to the voltage controlled oscillator.

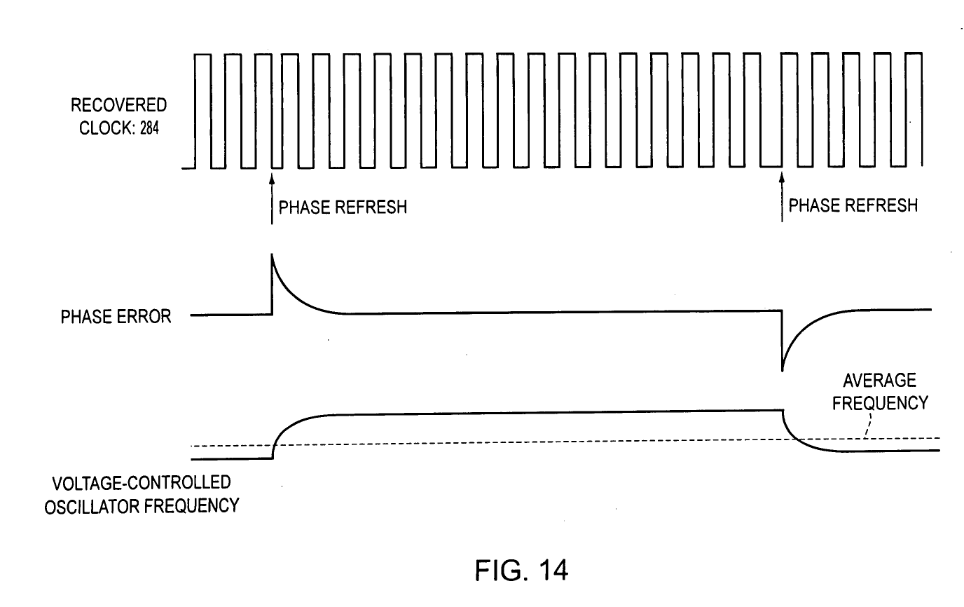

The operation of serial data link 200 is shown schematically in FIG. 14. The output frequency of voltage controlled oscillator 290 increases or decreases in response to the sign and magnitude of the phase error between the recovered clock 284 and the voltage controlled oscillator 290. Therefore, the circuit shown in FIG. 13 generates an output clock by adjusting the frequency, rather than the phase, of an oscillator. Therefore, a second oscillator 290 is required in the circuit of FIG. 13, which increases the cost and complexity of serial data link 200 compared to serial data link 100.

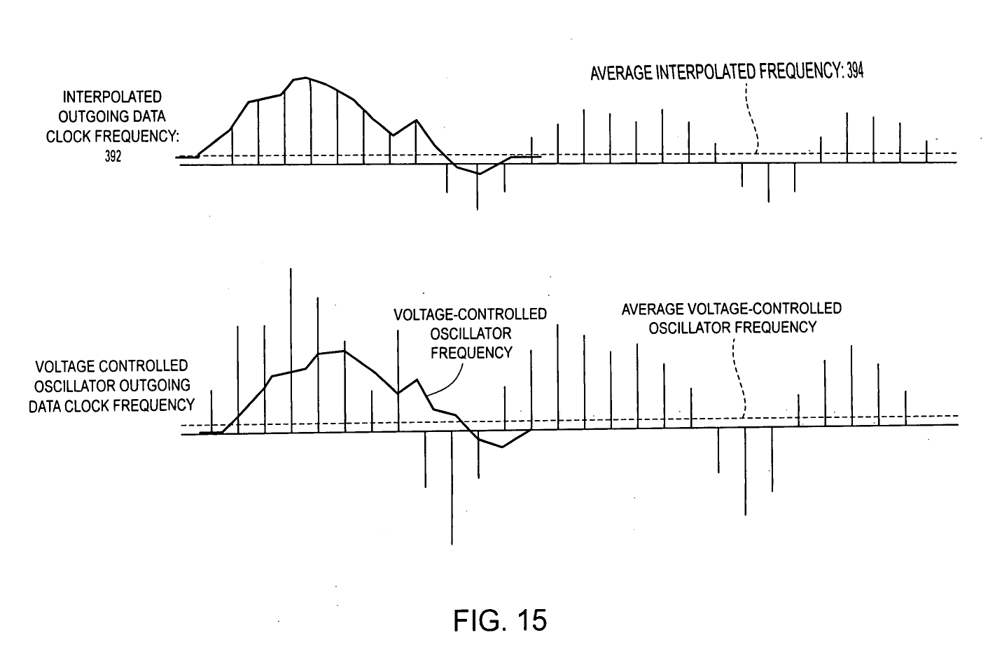

The performance of the low bandwidth phase-locked loop of FIG. 13 is compared to the performance of the dual phase interpolator of FIG. 3 by the diagram shown in FIG. 15. The outputs of both circuits in producing the outgoing data clock signal are qualitatively the same, although the outgoing data clock signal 292 produced by the voltage controlled oscillator 290 may be delayed somewhat compared to the interpolated outgoing data clock signal 192, because of the low bandwidth response of the phase-locked loop.

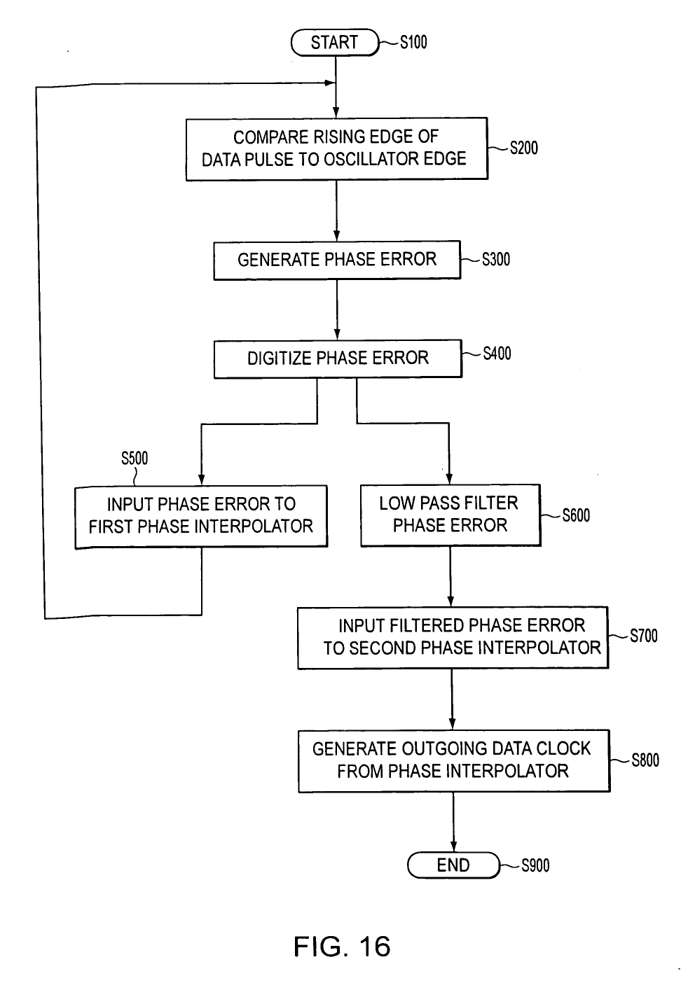

FIG. 16 is a flowchart of an exemplary method for implementing the dual phase interpolator technique described above. The method begins in step S100 and proceeds to step S200, wherein a rising (or falling) edge of a data pulse is compared to the corresponding edge of the oscillator signal. In step S300, a phase error is generated from the comparison. In step S400, the phase error is digitized into, for example, a six-bit value. The phase error is then delivered to the first phase interpolator in step S500. The phase error is also delivered to a low pass filter in step S600. The low pass filtered phase error is then delivered to the second phase interpolator in step S700. In step S800, the second phase interpolator generates the outgoing data clock signal based on the filtered phase error. The method then ends in step S900.

While details of this invention is described above in conjunction with the example outlined above, it is evident that many alternatives, modifications and variations are possible. For example, although details are described relative to a fiber optic application, the invention may be more broadly applicable to data links in general, which are required to re-transmit data in a synchronous fashion with respect to the incoming data. Moreover, although details are described as using digital components, in many portions of the circuit, analog components can replace the digital components. Accordingly, the exemplary implementations of the invention as set forth above are intended to be illustrative, not limiting.

What is claimed is:

1. An apparatus for generating an interpolated output signal, comprising:
an oscillator that generates a clock signal at a predefined frequency;
a first phase interpolator that receives the clock signal, the first phase interpolation generating a first interpolated output signal based on the clock signal and an error signal;
a low pass filter for filtering the error signal; and
a second phase interpolator that receives the clock signal and the filtered error signal, the second phase interpolator generating a second interpolated output signal based on the clock signal and the filtered error signal.

2. The apparatus of claim 1, further comprising:
a phase comparator that compares a phase of the first interpolated output signal with a phase of an incoming data signal to generate the error signal.

3. The apparatus of claim 1, wherein the second interpolated output signal and the first interpolated output signal have an average frequency that is based on a frequency of the incoming data signal.

4. The apparatus of claim 1, further comprising:
a clock and data recovery module, that compares edges of the clock signal with edges of data pulses of an incoming data signal to generate the error signal.

5. The apparatus of claim 4, further comprising a digitizer that digitizes values of the error signal.

6. The apparatus of claim 4, wherein the clock and data recovery module further detects the data pulses from the incoming data signal based on the first interpolated output signal.

7. The apparatus of claim 1, further comprising:
a serializer that re-transmits data pulses at a rate based on the second interpolated data signal.

8. The apparatus of claim 1, further comprising:
an electro-optic transducer that generates electrical signals from optical signals.

9. The apparatus of claim 1, further comprising:
an electro-optic transducer that generates optical signals from electrical signals.

10. The apparatus of claim 1, wherein the low-pass filter is a finite impulse response filter.

11. A method for generating an outgoing data clock, comprising:
generating an oscillator signal at a predefined frequency;
comparing edges of an incoming data signal to edges of an interpolated signal based on the oscillator signal;
generating an phase error signal based on the edge comparisons;
adjusting a phase of the interpolated signal based on the generated phase error signal;
low-pass filtering the phase error signal; and
generating an outgoing data clock based on the filtered phase error signal and the oscillator signal.

12. The method according to claim 11, further comprising:
transmitting outgoing data based on the outgoing data clock.

13. The method of claim 11, further comprising:
detecting digital data from the incoming data signal based on the interpolated signal.

14. The method of claim 13, further comprising:
re-fommatting the detected digital data into a format appropriate for a user's equipment; and
transmitting the re-formatted data to the user's equipment.

15. The method of claim 11, further comprising:
transforming optical signals into electrical signals; and
transforming electrical signals into optical signals.

16. The method of claim 11, further comprising:
digitizing the phase error signal.

17. The method of claim 14, further comprising:
transmitting the re-formatted data from the user's equipment;
storing the re-formatted data from the user's equipment; and
serializing the re-formatted data from the user's equipment.

18. The method of claim 11, wherein low-pass filtering the phase error signal comprises convolving the phase error signal with a finite impulse response filter.

19. An apparatus for generating an outgoing data clock, comprising:
means for generating an oscillator signal at a predefined frequency;
means for comparing edges of an incoming data signal to edges of an interpolated signal based on the oscillator signal;
means for generating an phase error signal based on the edge comparisons;
means for adjusting a phase of the interpolated signal based on the generated phase error signal;
means for low-pass filtering the phase error signal; and
means for generating an outgoing data clock based on the filtered phase error signal and the oscillator signal.
